(19) United States
(12) Patent Application Publication
(10) Pub. No.: US 2009/0038548 A1
(43) Pub. Date: Feb. 12, 2009

(54) SUBSTRATE TREATING APPARATUS AND TREATING GAS EMITTING MECHANISM

(75) Inventors: Hachishiro Iizuka, Hyogo (JP); Tomoyuki Sakoda, Yamanashi (JP); Naofumi Oda, Yamanashi (JP); Norihiko Tsuji, Yamanashi (JP); Masayuki Moroi, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, MINATO-KU, TOKYO (JP)

(21) Appl. No.: 12/162,132

(22) PCT Filed: Mar. 30, 2007
(86) PCT No.: PCT/JP2007/057096

§ 371 Date: Aug. 15, 2008

(30) Foreign Application Priority Data
Mar. 31, 2006 (JP) 2006-097946

(51) Int. Cl. C23C 16/455

(52) U.S. Cl. 118/724

(57) ABSTRACT

A film forming apparatus includes a process chamber 2 configured to accommodate a semiconductor wafer W; a worktable 5 disposed inside the process chamber 2 and configured to place the semiconductor wafer W thereon; a showerhead 40 used as a process gas delivery mechanism disposed to face the worktable 5 and configured to delivery a process gas into the process chamber 2; and an exhaust unit 101 configured to exhaust gas from inside the process chamber 2, wherein the showerhead 40 has a gas passage formed therein for supplying the process gas, and an annular temperature adjusting cell 400 formed therein around the gas passage.

### TECHNICAL FIELD

The present invention relates to a substrate processing apparatus for performing a process, such as film formation, on a target substrate, such as a semiconductor wafer, and a process gas delivery mechanism for delivering a process gas toward a target substrate in a substrate processing apparatus.

### BACKGROUND ART

In the process of manufacturing various semiconductor devices, thin films of various materials are formed on a target object, such as a semiconductor wafer (which may be simply referred to as “wafer”). Along with recent diversification of physicality required to thin films of this kind, combination of materials used for forming the thin films has been more diversified and complicated. For example, as regards semiconductor memory devices, in order to overcome a limit of the performance of DRAM (Dynamic Random Access Memory) devices due to their refresh operation, high-capacity memory devices have been developed by use of a ferroelectric capacitor including a ferroelectric thin film. A ferroelectric memory device (Ferroelectric Random Access Memory: FeRAM) including a ferroelectric thin film is one type of the nonvolatile memory devices, and has attracted attentions as a memory device of the next generation, because this device needs no refresh operation in principle, can sustain stored data when the power is shut off, and can provide an operation speed comparable with DRAMs

The ferroelectric thin films of FeRAMs are made of a insulative material, such as SrBi₂Ta₂O₉ (SBT) or Pb(Zr, Ti)O₃ (PZT). A method suitable for forming such a thin film, which has a complex composition of a plurality of elements, to have a small thickness with high accuracy is an MOCVD technique arranged to utilize thermal decomposition of a gasified organic metal compound.

In general, not only the MOCVD technique, but also the other CVD techniques are arranged to heat a wafer placed on a worktable inside a film forming apparatus while supplying a source gas from a showerhead opposite to the worktable. Consequently, the source gas causes thermal decomposition and/or reduction reaction, thereby forming a thin film on the wafer. In order to uniformly supply the gas, the showerhead is provided with a flat gas diffusion space formed therein to have a size almost the same as the wafer diameter. A number of gas spouting holes are formed on the counter surface of the showerhead in a dispersion pattern and communicate with the gas diffusion space (for example, WO 2005/024928).

In the film forming apparatus described above, the showerhead has a larger diameter than the wafer or the worktable for placing the wafer thereon, such that the wafer has a diameter of 200 mm and the showerhead has an outer diameter of 460 to 470 mm, for example. As described above, the showerhead typically has the flat gas diffusion space formed therein, which prevents heat transmission (heat release) to the backside thereof. Accordingly, when the showerhead is heated by radiant heat from the worktable for heating the wafer, the temperature of the central portion of the showerhead is increased along with repetition of film formation. On the other hand, since the showerhead has a larger diameter than the worktable opposite thereto, the peripheral portion of the showerhead is relatively less affected by radiant heat from the worktable. Further, unlike the central portion corresponding to the gas diffusion space, the peripheral portion has a larger heat release amount from the top of the showerhead. Accordingly, the temperature of the peripheral portion tends to be far lower than that of the central portion.

It is known that, in general, where the peripheral portion of a wafer placed on a worktable has a temperature lower than the central portion, some characteristics of film formation are adversely affected. For example, the composition of a film thus formed may be less uniform on the surface of the wafer, i.e., a film formation characteristic may be deteriorated. In light of this problem, there is a technique arranged to heat the peripheral area of a worktable outside the wafer support area, thereby supplying heat to the wafer peripheral portion from outside and increasing the temperature of the wafer peripheral portion. However, where the temperature of the peripheral area of the worktable is increased, that portion of the showerhead opposite to the peripheral area of the worktable (i.e., a portion inward from the peripheral portion of the showerhead) receives radiant heat from the worktable and easily increases its temperature.

Because of the reasons described above, when a film formation process is repeatedly performed, a temperature distribution is formed on the showerhead such that the temperature of the peripheral portion is far lower than that of the central portion. Where the temperature of the showerhead thus becomes uneven, some characteristics of film formation, such as the uniformity of film composition, are adversely affected, and/or deposition can be easily generated on the peripheral portion of the showerhead, which has a lower temperature.

### DISCLOSURE OF INVENTION

An object of the present invention is to provide a substrate processing apparatus that can suppress deterioration in process performance and/or uniformity due to uneven temperature of a process gas delivery mechanism, such as a showerhead.

Another object of the present invention is to provide a process gas delivery mechanism that can prevent the temperature thereof from becoming uneven.

According to a first aspect of the present invention, there is provided a substrate processing apparatus comprising: a process chamber configured to accommodate a target substrate; a worktable disposed inside the process chamber and configured to place the target substrate thereon; a process gas delivery mechanism disposed to face the target substrate on the worktable and configured to delivery a process gas into the process chamber; and an exhaust mechanism configured to exhaust gas from inside the process chamber, wherein the process gas delivery mechanism has a multi-layered structure comprising a plurality of plates having a gas passage formed therein for supplying the process gas, and the multi-layered structure includes an annular temperature adjusting cell formed therein around the gas passage.

In the first aspect, the multi-layered structure may comprise a first plate from which the process gas is introduced, a second plate set in contact with a main surface of the first plate, and a third plate set in contact with the second plate and having a plurality of gas delivery holes formed therein according to the target substrate placed on the worktable. In this case, the temperature adjusting cell may be defined by a recess formed in any one of the first plate, the second plate, or the third plate and a plate surface adjacent thereto.

The temperature adjusting cell may be defined by an annular recess formed on the lower surface of the second plate and an upper surface of the third plate. Alternatively, the temperature adjusting cell may be defined by a lower surface of the second plate and an annular recess formed on the upper surface of the third plate.

The recess may be provided with a plurality of heat transfer columns formed therein and set in contact with an adjacent plate. In this case, the heat transfer columns may be arrayed in a concentric pattern with array intervals set to be larger toward an outer perimeter of the plates. Alternatively, the heat transfer columns may be arrayed in a concentric pattern with cross sectional areas set to be smaller toward an outer perimeter of the plates.

The recess may be provided with a plurality of heat transfer walls formed therein and set in contact with an adjacent plate. In this case, the heat transfer walls may be arrayed in a concentric pattern with array intervals set to be larger toward an outer perimeter of the plates. Alternatively, the heat transfer walls may be arrayed in a concentric pattern with cross sectional areas set to be smaller toward an outer perimeter of the plates.

The mechanism may further include a feed passage for supplying a temperature adjusting medium into the temperature adjusting cell and an exhaust passage for exhausting the temperature adjusting medium. Alternatively, the mechanism may further include a feed passage for supplying a temperature adjusting medium into the temperature adjusting cell, and the temperature adjusting cell may be set to communicate with a process space inside the process chamber.

The third plate may have a plurality of first delivery holes for delivering a first process gas and a plurality of second delivery holes for delivering a second process gas. In this case, the apparatus may be arranged such that the gas passage is provided with a first gas diffusion area disposed between the first plate and the second plate, and a second gas diffusion area disposed between the second plate and the third plate, wherein the first gas diffusion area includes a plurality of first columns connected to the first plate and the second plate, and a first gas diffusion space forming a portion other than the plurality of first columns and communicating the first gas delivery holes, wherein the second gas diffusion area includes a plurality of second columns connected to the second plate and the third plate, and a second gas diffusion space forming a portion other than the plurality of second columns and communicating the second gas delivery holes, and wherein the first process gas is supplied through the first gas diffusion space and delivered from the first gas delivery holes, and the second process gas is supplied through the second gas diffusion space and delivered from the second gas delivery holes.

The plurality of second columns may respectively have gas passages formed therein in an axial direction for the first gas diffusion space to communicate with the first gas delivery holes.

According to a second aspect of the present invention, there is provided a process gas delivery mechanism for delivering a process gas into a process chamber in which a gas process is performed on a target substrate by use of the process gas thus supplied, the process gas delivery mechanism comprising: a multi-layered structure comprising a plurality of plates having a gas passage formed therein for supplying the process gas, wherein the multi-layered structure includes an annular temperature adjusting cell formed therein around the gas passage.

According to the present invention, the multi-layered structure used as a process gas delivery mechanism, such as a showerhead is provided with the annular temperature adjusting cell around the gas passage, so that the temperature of the process gas delivery mechanism at the peripheral portion can be adjusted. Consequently, the temperature unevenness of the process gas delivery mechanism is collected, and particularly the temperature uniformity on the surface of the process gas delivery mechanism is greatly improved, so the film formation uniformity is improved.

### BRIEF DESCRIPTION OF DRAWINGS

FIG. 1 This is a sectional view showing a film forming apparatus according to an embodiment of the present invention.

FIG. 2 This is a perspective plan view showing an example of the bottom structure of a casing used in the film forming apparatus.

FIG. 3 This is a top plan view showing the casing of the film forming apparatus.

FIG. 4 This is a top plan view showing the shower base of a showerhead used in the film forming apparatus.

FIG. 5 This is a bottom plan view showing the shower base of the showerhead used in the film forming apparatus.

FIG. 6 This is a top plan view showing the gas diffusion plate of the showerhead used in the film forming apparatus.

FIG. 7 This is a bottom plan view showing the gas diffusion plate of the showerhead used in the film forming apparatus.

FIG. 8 This is a top plan view showing the shower plate of the showerhead used in the film forming apparatus.

FIG. 9 This is a sectional view showing the shower base taken along a line IX-IX in FIG. 4.

FIG. 10 This is a sectional view showing the diffusion plate taken along a line X-X in FIG. 6.

FIG. 11 This is a sectional view showing the shower plate taken along a line XI-XI in FIG. 8.

FIG. 12 This is an enlarged view showing an arrangement of heat transfer columns.

FIG. 13 This is a view showing an alternative example of heat transfer columns.

FIG. 14 This is a view showing another alternative example of heat transfer columns.

FIG. 15 This is a view showing another alternative example of heat transfer columns.

FIG. 16 This is a bottom plan view showing a gas diffusion plate according to an alternative embodiment.

FIG. 17 This is a bottom plan view showing a gas diffusion plate according to another alternative embodiment.

FIG. 18 This is a sectional view showing a film forming apparatus according to an alternative embodiment.

FIG. 19 This is a sectional view showing a film forming apparatus according to another alternative embodiment.

FIG. 20 This is a bottom plan view showing a gas diffusion plate used in the film forming apparatus shown in FIG. 19.

FIG. 21 This is a sectional view showing a film forming apparatus according to an alternative embodiment.

FIG. 22 This is a top plan view showing a main portion of a gas diffusion plate used in the film forming apparatus shown in FIG. 21.

FIG. 23 This is a sectional view showing the gas diffusion plate used in the film forming apparatus shown in FIG. 21.

FIG. 24 This is a diagram showing the structure of a gas supply source section used in a film forming apparatus according to a first embodiment of the present invention.

FIG. 25 This is a view schematically showing the structure of a control section.

### BEST MODE FOR CARRYING OUT THE INVENTION

Preferable embodiments of the present invention will now be described with reference to the accompanying drawings.

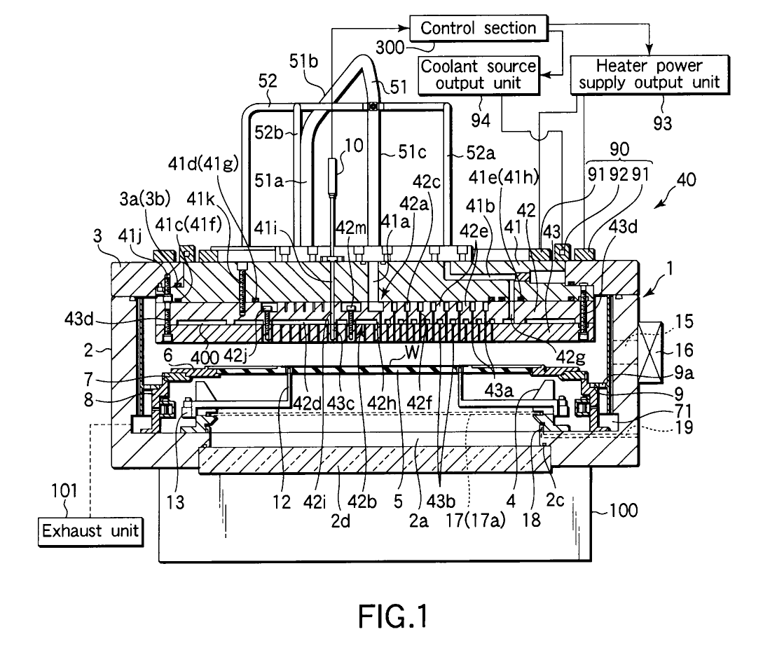

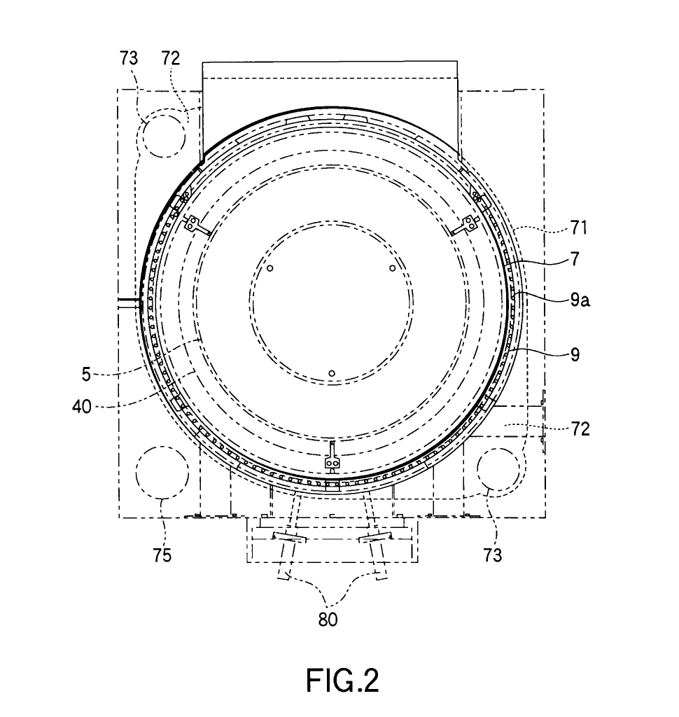

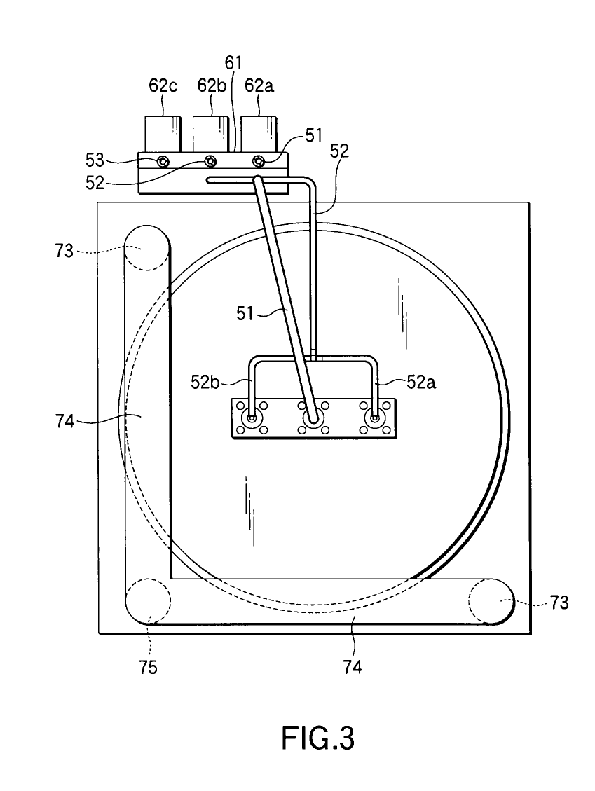

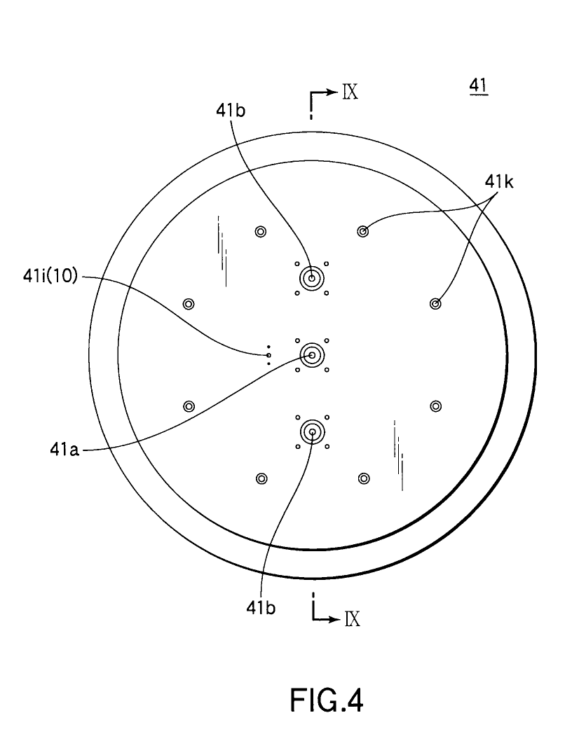

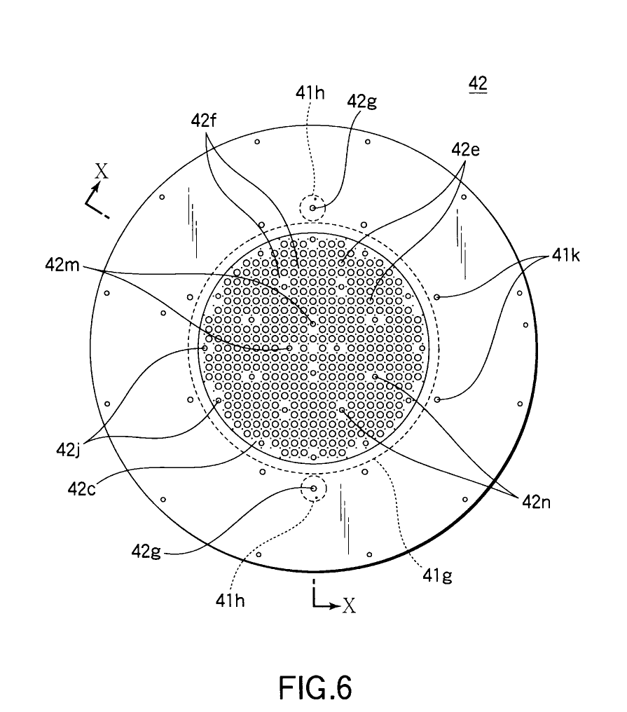

FIG. 1 is a sectional view showing a film forming apparatus, which is a substrate processing apparatus according to an embodiment of the present invention. FIG. 2 is a top plan view showing the internal structure of the casing of the film forming apparatus. FIG. 3 is a top plan view showing the top of the casing. FIGS. 4 to 11 are views showing some components of a showerhead used in the film forming apparatus. The cross section of the showerhead shown in FIG. 1 corresponds to a portion taken along a line X-X in FIG. 6 described later, and has an asymmetrical structure between the right and left sides relative to, the central portion.

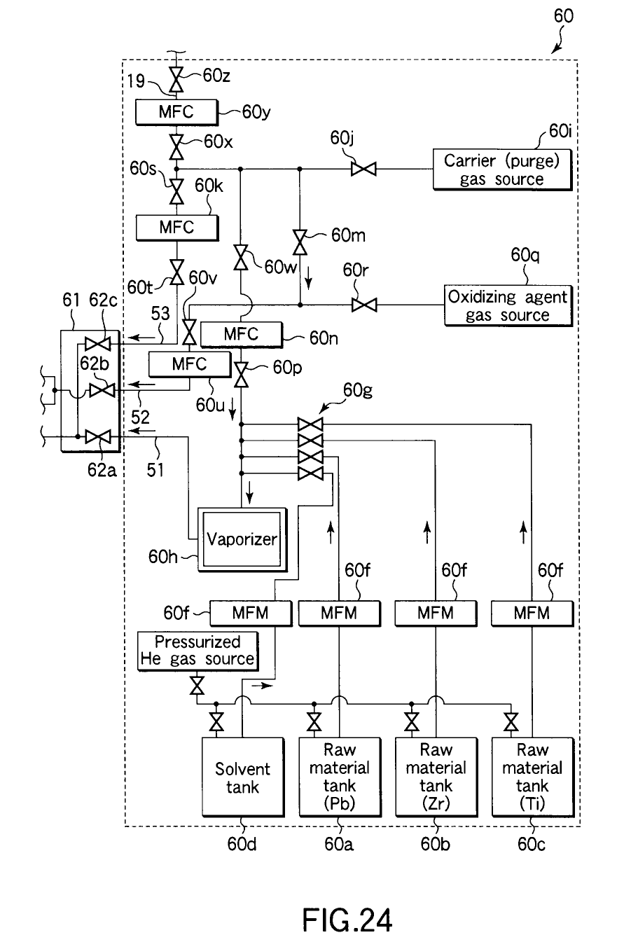

As shown in FIG. 1, this film forming apparatus includes a casing 1 made of, e.g., aluminum and having an essentially rectangular shape in a sectional plan view. The inside of the casing 1 defines a cylindrical process chamber 2 with a bottom having an opening 2a connected to a lamp unit 100. A quartz transmission window 2d is fixed to the opening 2a from outside, through a seal member 2c formed of an O-ring, so that the process chamber 2 is airtightly closed. The top of the process chamber 2 is closed by a detachable lid 3, which supports a gas delivery mechanism or showerhead 40. The showerhead 40 will be described later in detail. Although not shown in FIG. 1, a gas supply source section 60 (see FIG. 24) is disposed behind the casing 1 to supply various gases into the process chamber through the showerhead 40, as described later. The gas supply source section 60 is connected to a source gas line 51 for supplying a source gas and an oxidizing agent gas line 52 for supplying an oxidizing agent gas. The oxidizing agent gas line 52 is divided into oxidizing agent gas branch lines 52a and 52b. The source gas line 51 and oxidizing agent gas branch lines 52a and 52b are connected to the showerhead 40.

A cylindrical shield base 8 is disposed inside the process chamber 2 such that it stands on the bottom of the process chamber 2. The shield base 8 has an opening at the top, which is provided with an annular base ring 7. The inner perimeter of the base ring 7 supports an annular attachment 6, and the inner perimeter of the attachment 6 has a step portion that supports a worktable 5 configured to place a wafer W thereon. A baffle plate 9 is disposed outside the shield base 8, as described below.

The baffle plate 9 has a plurality of exhaust holes 9a formed therein. A bottom exhaust passage 71 is formed around the shield base 8 on the periphery of the bottom of the process chamber 2. The interior of the process chamber 2 communicates with the exhaust passage 71 through the exhaust holes 9a of the baffle plate 9, so that gas is uniformly exhausted from inside the process chamber 2. An exhaust unit 101 is disposed below the casing 1 to exhaust the interior of the process chamber 2. Exhaust by the exhaust unit 101 will be described later in detail.

As described above, the lid 3 is disposed on the opening at the top of the process chamber 2. The showerhead 40 is attached to the lid 3 at a position to be opposite to the wafer W placed on the worktable 5.

A cylindrical reflector 4 is disposed in a space surrounded by the worktable 5, attachment 6, base ring 7, and shield base 8, such that it stands on the bottom of the process chamber 2. The reflector 4 is configured to reflect and guide heat rays radiated from the lamp unit (not shown) onto the backside of the worktable 5, so that the worktable 5 is efficiently heated. The heat source is not limited to the lamp described above, and it may be formed of a resistance heating element embedded in the worktable 5 to heat the worktable 5.

The reflector 4 has slit portions at, e.g., three positions, and lifter pins 12 are disposed at positions corresponding to the slit portions and movable up and down to move the wafer W relative to the worktable 5. Each of the lifter pins 12 has a pin portion and a support portion integrally formed with each other. The lifter pins 12 are supported by an annular holder 13 disposed around the reflector 4, so that they are moved up and down along with the holder 13 moved up and down by an actuator (not shown). The lifter pins 12 are made of a material, such as quartz or ceramic (Al₂O₃, AlN, or SiC), which can transmit heat rays radiated from the lamp unit.

When the wafer W is transferred, the lifter pins 12 are moved up to project from the worktable 5 by a predetermined length. On the other hand, when the wafer W supported on the lifter pins 12 is placed on the worktable 5, the lifter pins 12 are moved down to retreat inside the worktable 5.

The reflector 4 is disposed on the bottom of the process chamber directly below the worktable 5 to surround the opening 2a. The inner perimeter of the reflector 4 supports the periphery of a gas shield 17 all around, which is made of a heat ray transmission material, such as quartz. The gas shield 17 has a plurality of holes 17a formed therein.

The space formed between the gas shield 17 supported by the inner perimeter of the reflector 4 and the transmission window 2d is connected to a purge gas supply mechanism for supplying a purge gas (for example, an inactive gas, such as N₂ or Ar gas). The purge gas is supplied through a purge gas passage 19 formed in the bottom of the process chamber 2 and gas spouting holes 18 formed equidistantly at eight lower positions on the inside of the reflector 4 and communicating with the purge gas passage 19.

The purge gas thus supplied flows through the holes 17a of the gas shield 17 onto the backside of the worktable 5. Consequently, a process gas supplied from the showerhead 40 as described later is prevented from entering the space on the backside of the worktable 5 or causing damage to the transmission window 2d due to, e.g., thin film deposition and/or etching.

The casing 1 has a wafer transfer port 15 formed in the sidewall and communicating with the process chamber 2. The wafer transfer port 15 is connected to a load-lock chamber (not shown) through a gate valve 16.

As exemplified in FIG. 2, the annular bottom exhaust passage 71 communicates with exhaust confluence portions 72 formed on the bottom of the casing 1 at diagonally opposite positions to be symmetrical relative to the process chamber 2 interposed therebetween. The exhaust confluence portions 72 are connected to the exhaust unit 101 (see FIG. 1) located below the casing 1, through upward exhaust passages 73 disposed inside corners of the casing 1, horizontal exhaust pipes 74 (see FIG. 3) disposed on the top of the casing 1, and a downward exhaust passage 75 penetrating a corner of the casing 1. The upward exhaust passages 73 and downward exhaust passage 75 are disposed by use of idle spaces at corners of the casing 1, so that formation of the exhaust passages is completed within the foot print of the casing 1. In this case, the installation area of the apparatus is not increased, or the thin film forming apparatus can be installed while saving the occupied space.

The worktable 5 is provided with a plurality of thermo couples 80, such that one of them is near the center and another one is near the edge, for example. The temperature of the worktable 5 is measured by the thermo couples 80, and is controlled in accordance with measurement results obtained by the thermo couples 80.

Next, a detailed explanation will be given of the showerhead 40.

The showerhead 40 includes a cylindrical shower base (first plate) 41 having an outer perimeter to be coupled with an upper portion of the lid 3, a disk-like gas diffusion plate (second plate) 42 set in close contact with the lower surface of the shower base 41, and a shower plate (third plate) 43 mounted on the lower surface of the gas diffusion plate 42. The shower base 41 on the uppermost position of the showerhead 40 is configured to discharge heat of the entire showerhead 40 outside. The showerhead 40 is formed of a cylindrical column as a whole, but it may be formed of a rectangular column.

The shower base 41 is fixed to the lid 3 by base fixing screws 41j. The junction between the shower base 41 and lid 3 is provided with a lid O-ring groove 3a and a lid O-ring 3b, so that they are airtightly coupled with each other.

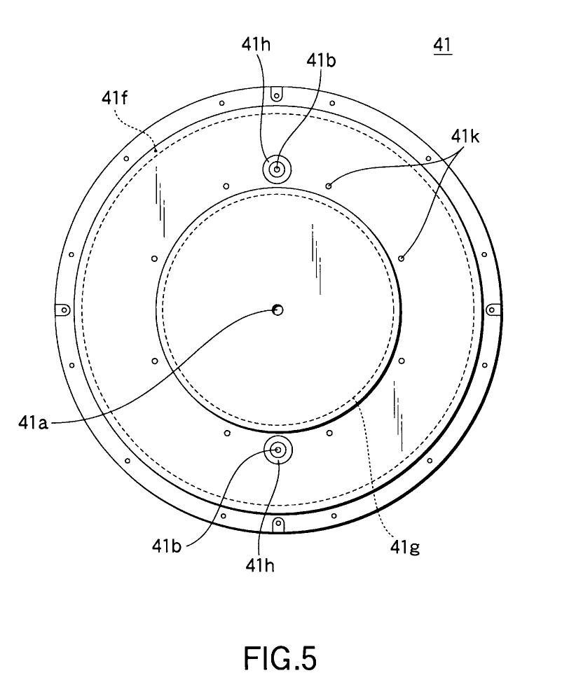

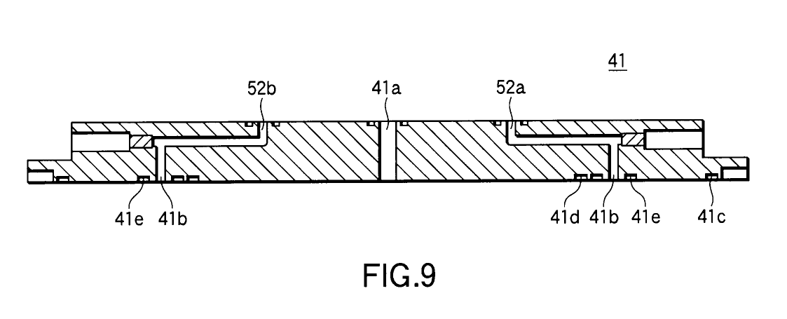

FIG. 4 is a top plan view showing the shower base 41. FIG. 5 is a bottom plan view showing the shower base 41. FIG. 9 is a sectional view taken along a line IX-IX in FIG. 4. The shower base 41 has a first gas feed passage 41a formed at the center and connected to the source gas line 51, and a plurality of second gas feed passages 41b connected to the oxidizing agent gas branch lines 52a and 52b of the oxidizing agent gas line 52. The first gas feed passage 41a vertically extends and penetrates the shower base 41. Each of the second gas feed passages 41b has a hook shape that first vertically extends from the inlet to a middle level of the shower base 41, then horizontally extends at this middle level, and then vertically extends again. In FIG. 1, the oxidizing agent gas branch lines 52a and 52b are located at positions symmetrical about the first gas feed passage 41a interposed therebetween, but they may be located at any other positions as long as they can uniformly supply gas.

The lower surface of the shower base 41 (the face set in contact with the gas diffusion plate 42) has an outer perimeter O-ring groove 41c and an inner perimeter O-ring groove 41d, in which an outer perimeter O-ring 41f and an inner perimeter O-ring 41g are respectively fitted, so that the junction therebetween is kept airtight. Further, a gas passage O-ring groove 41e and a gas passage O-ring 41h are disposed around the opening of each of the second gas feed passages 41b. Consequently, the source gas and oxidizing agent gas are reliably prevented from being mixed with each other.

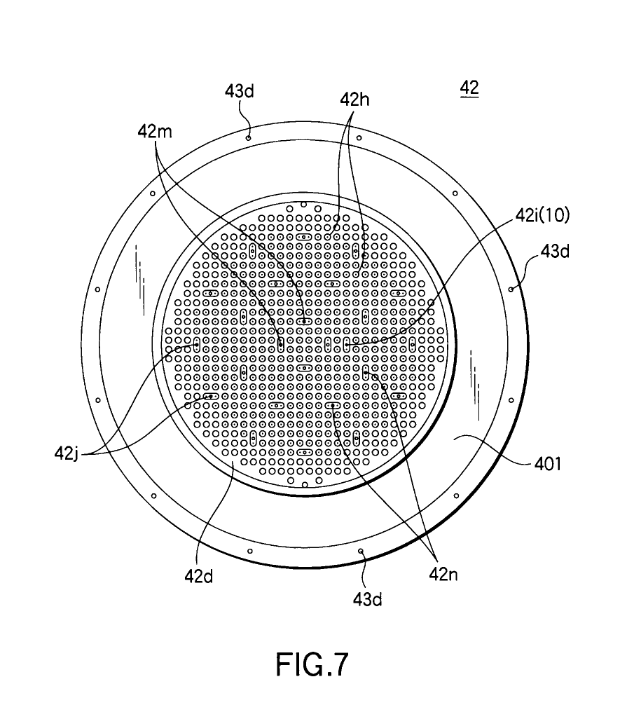

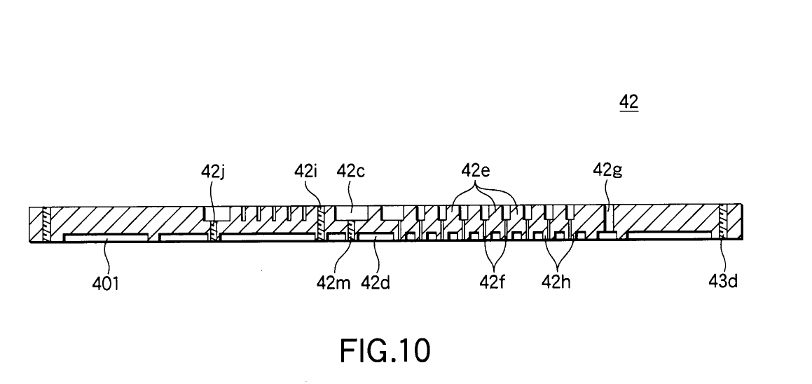

The gas diffusion plate 42 having gas passages is disposed on the lower surface of the shower base 41. FIG. 6 is a top plan view showing the gas diffusion plate 42. FIG. 7 is a bottom plan view showing the gas diffusion plate 42. FIG. 10 is a sectional view taken along a line X-X in FIG. 6. A first gas diffusion area 42a and a second gas diffusion area 42b are respectively formed on the upper surface and lower surface of the gas diffusion plate 42. An annular temperature adjusting cell 400 for forming a temperature adjusting space is formed on the gas diffusion plate 42 to surround the second gas diffusion area 42b. This temperature adjusting cell 400 is a bore defined by a recess (annular groove) 401 formed on the lower surface of the gas diffusion plate 42 and the upper surface of the shower plate 43. The temperature adjusting cell 400 serves as a heat-insulating space inside the showerhead 40, which suppresses upward heat release through the gas diffusion plate 42 and shower base 41 at the peripheral portion of the showerhead 40. Consequently, the temperature decrease at the peripheral portion of the showerhead 40 is suppressed, although, in general, the peripheral portion can more easily cause a temperature decrease than the central portion. It follows that the temperature of the showerhead 40 becomes more uniform, and particularly the temperature of the shower plate 43 at the portion facing the worktable 5 becomes more uniform.

A temperature adjusting cell 400 may be defined by the lower surface of the gas diffusion plate 42 and an annular recess formed on the upper surface of the shower plate 43.

A temperature adjusting cell 400 may be defined by the shower base 41 and gas diffusion plate 42. In this case, a temperature adjusting cell 400 may be defined by an annular recess formed on the lower surface of the shower base 41 and the upper surface of the gas diffusion plate 42. Alternatively, a temperature adjusting cell 400 may be defined by the lower surface of the shower base 41 and an annular recess formed on the upper surface of the gas diffusion plate 42. However, in order to provide a uniform composition of a film to be formed, an important factor is the temperature uniformity of the shower plate 43, which forms the lowermost surface of the showerhead 40 and thus faces the wafer W placed on the worktable 5. Accordingly, a temperature adjusting cell 400 is preferably formed at a position that can effectively suppress the temperature decrease at the peripheral portion of the shower plate 43. In light of this, a temperature adjusting cell 400 is preferably formed between the gas diffusion plate 42 and shower plate 43 by use of a recess formed on either of them.

The first gas diffusion area 42a on the upper side has a plurality of heat transfer columns 42e respectively formed of cylindrical column projections distributed at positions other than the openings of the first gas passages 42f. The space around the heat transfer columns 42e serves as a first gas diffusion space 42c. The heat transfer columns 42e have a height essentially equal to the depth of the first gas diffusion area 42a, and are set in close contact with the shower base 41 on the upper side to transmit heat from the shower plate 43 on the lower side to the shower base 41.

The second gas diffusion area 42b on the lower side has a plurality of cylindrical column projections 42h, so that the space around the cylindrical column projections 42h serves as a second gas diffusion space 42d. The second gas diffusion space 42d communicates with the second gas feed passages 41b of the shower base 41 through second gas passages 42g vertically penetrating the gas diffusion plate 42. Of the cylindrical column projections 42h, projections 42h within an area not smaller than the target object, and preferably not less than 10% larger than the target object, respectively have first gas passages 42f formed at the center to penetrate them. The cylindrical column projections 42h have a height essentially equal to the depth of the second gas diffusion area 42b, and are set in close contact with the upper surface of the shower plate 43 on the lower side of the gas diffusion plate 42. Those of the cylindrical column projections 42h having the first gas passages 42f are arranged such that the first gas passages 42f communicate with first gas delivery holes 43a described later, which are formed in the shower plate 43 set in close contact with the gas diffusion plate 42 on the lower side. All of the cylindrical column projections 42h may have the first gas passages 42f formed therein.

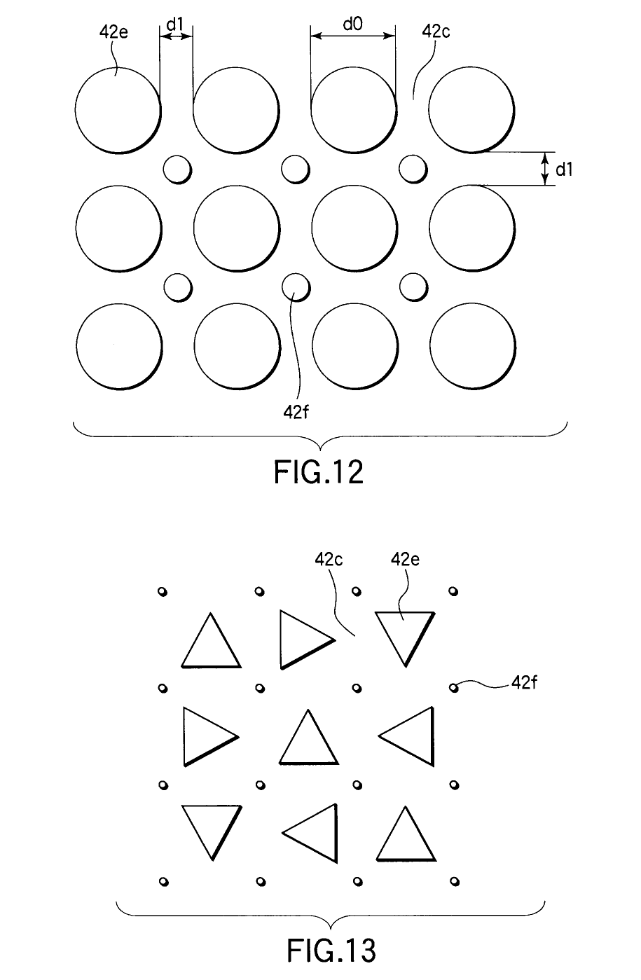

As shown in the enlarged view of FIG. 12, each of the heat transfer columns 42e has a diameter d0 of, e.g., 2 to 20 mm, and preferably of 5 to 12 mm. Adjacent heat transfer columns 42e are separated by a distance d1 of e.g., 2 to 20 mm, and preferably of 2 to 10 mm. The heat transfer columns 42e are preferably arranged such that the total value S1 of the cross sectional areas of the heat transfer columns 42e has a ratio (area ratio R=(S1/S2)) of 0.05 to 0.50 relative to the cross sectional area S2 of the first gas diffusion area 42a. If this area ratio R is smaller than 0.05, the effect of improving the heat transmission efficiency to the shower base 41 becomes too low, and thereby deteriorates the heat release characteristic. If this area ratio R is larger than 0.50, the gas flow resistance of the first gas diffusion space 42c becomes too large, and thereby deteriorates the gas flow uniformity and may increase the planar unevenness (or deteriorate the uniformity) of the thickness of a film formed on a substrate. Further, in this embodiment, as shown in FIG. 12, the distance between each of the first gas passages 42f and the adjacent one of the heat transfer columns 42e is constant. However, this arrangement is not limiting, and the heat transfer columns 42e may be located at any positions among the first gas passages 42f.

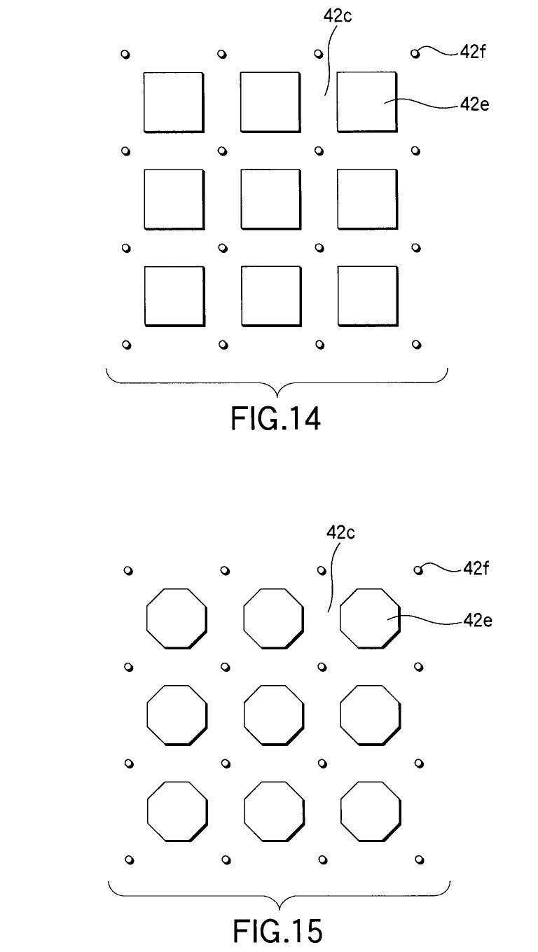

The cross sectional shape of the heat transfer columns 42e preferably has a shape with a curved surface, such as a circle as shown in FIG. 12 or an ellipse, because it renders a small flow resistance. However, this shape may be a polygon, such as a triangle as shown in FIG. 13, a rectangle as shown in FIG. 14, or an octagon as shown in FIG. 15.

The array of the heat transfer columns 42e is preferably set to form a latticed or staggered pattern. The first gas passages 42f are preferably formed at the centers of a latticed or staggered pattern of the heat transfer columns 42e. For example, where the heat transfer columns 42e are formed of cylindrical columns having a diameter d0 of 8 mm and a distance d1 of 2 mm, and they are arrayed in a latticed pattern, the area ratio R is 0.44. The dimensions and arrangement of the heat transfer columns 42e thus determined can improve both of the heat transfer efficiency and gas flow uniformity. The area ratio R may be suitably adjusted in accordance with various gases.

A plurality of diffusion plate fixing screws 41k are disposed at a plurality of positions near the peripheral portion of the first gas diffusion area 42a (near and outside the inner perimeter O-ring groove 41d) to set the upper ends of the heat transfer columns 42e of the first gas diffusion area 42a in close contact with the lower surface of the shower base 41 on the upper side. The diffusion plate fixing screws 41k generate a fastening force for reliably setting the heat transfer columns 42e of the first gas diffusion area 42a in close contact with the lower surface of the shower base 41, so that the heat transfer resistance therebetween is decreased and the heat transfer columns 42e thereby provides a reliable heat transfer effect. The fixing screws 41k may be attached to the heat transfer columns 42e of the first gas diffusion area 42a.

Unlike a partition wall, a plurality of heat transfer columns 42e disposed inside the first gas diffusion area 42a do not partition the space. Accordingly, the first gas diffusion space 42c is not divided but continuous, so the gas supplied into the first gas diffusion space 42c is diffused over the entire space before it is delivered downward.

Further, since the first gas diffusion space 42c is continuous as described above, the source gas can be supplied into the first gas diffusion space 42c through one first gas feed passage 41a and one source gas line 51. This makes it possible to decrease the number of connecting positions between the source gas line 51 and showerhead 40 and to simplify (shorten) the circuitry route for the same. Where the route of the source gas line 51 is thus shortened, the supply and stop of the source gas from the gas supply source section 60 through the piping panel 61 can be controlled with high accuracy, and the occupied space of the entire apparatus is decreased.

As shown in FIG. 1, the source gas line 51 is formed as an arch as a whole, which includes a vertical rising portion 51a through which the source gas flows vertically upward, a slant rising portion 51b connected thereto and extending obliquely upward, and a falling portion 51c connected thereto. Each of the connecting portion between the vertically rising portion 51a and slant rising portion 51b and the connecting portion between the slant rising portion 51b and falling portion 51c has a gently curved shape (with a large curvature radius). This arrangement is adopted to prevent a pressure variation from being caused halfway through the source gas line 51.

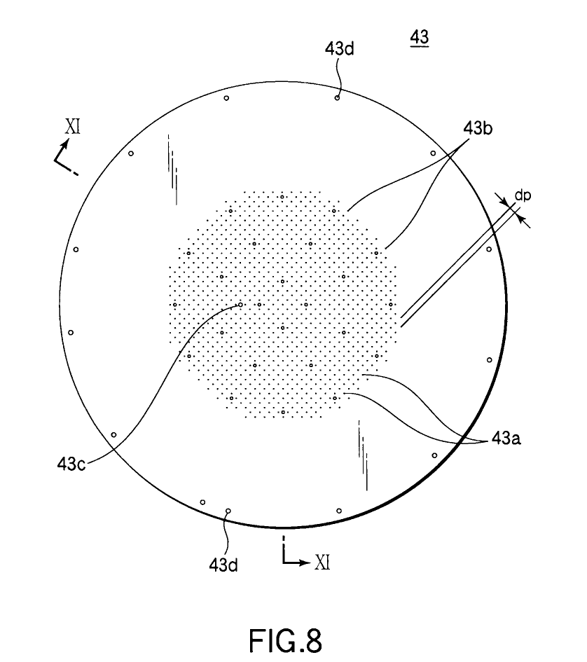

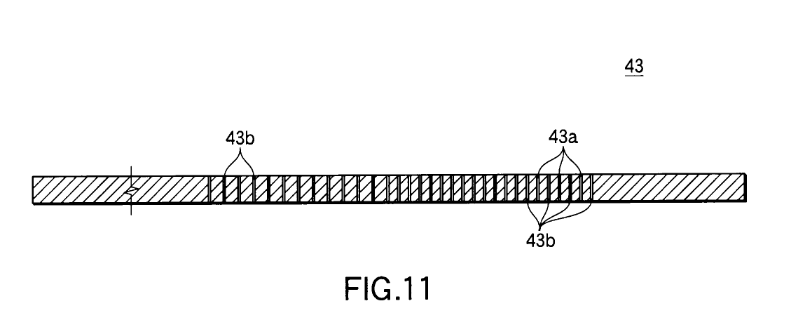

The lower surface of the gas diffusion plate 42 described above supports the shower plate 43 attached thereto by a plurality of fixing screws 42j, 42m, and 42n arrayed in an annular direction and inserted from the upper surface of the gas diffusion plate 42. The fixing screws are inserted from the upper surface of the gas diffusion plate 42, because, if a screw thread or screw groove was formed on the surface of the shower plate 43 alternatively, the film formed on the surface of the showerhead 40 could be easily peeled off. Next, the shower plate 43 will be explained. FIG. 8 is a top plan view showing the shower plate 43. FIG. 11 is a sectional view taken along a line XI-XI in FIG. 8.

The shower plate 43 has a plurality of first gas delivery holes 43a and a plurality of second gas delivery holes 43b formed therein to be alternately adjacent to each other. Specifically, the first gas delivery holes 43a respectively communicate with the first gas passages 42f of the gas diffusion plate 42 on the upper side. The second gas delivery holes 43b communicate with the second gas diffusion space 42d of the second gas diffusion area 42b of the gas diffusion plate 42 on the upper side, i.e., they are disposed in the gap between the cylindrical column projections 42h.

The shower plate 43 is structured such that the second gas delivery holes 43b connected to the oxidizing agent gas line 52 are disposed on the outermost peripheral side, while the first gas delivery holes 43a and second gas delivery holes 43b are alternately and uniformly arrayed on the inner side surrounded by the peripheral side. For example, the array pitch dp of the first gas delivery holes 43a and second gas delivery holes 43b alternately arrayed is set at 7 mm, the number of first gas delivery holes 43a is 460, and the number of second gas delivery holes 43b is 509. The array pitch dp and the numbers are suitably set in accordance with the target object size and film formation characteristics.

The shower plate 43, gas diffusion plate 42, and shower base 41 of the showerhead 40 are connected to each other by stud screws 43d arrayed in the peripheral portion.

The shower base 41, gas diffusion plate 42, and shower plate 43 stacked one on the other are respectively provided with a thermo couple insertion hole 41i, a thermo couple insertion hole 42i, and a thermo couple insertion hole 43c to be aligned with each other in the thickness direction. A thermo couple 10 is inserted in the holes to measure the temperature of the lower surface of the shower plate 43 and the inside of the showerhead 40. Thermo couples 10 may be respectively disposed at the central and peripheral portions, so as to control the temperature of the lower surface of the shower plate 43 more uniformly with high accuracy. In this case, the substrate can be uniformly heated to perform film formation with improved planar uniformity.

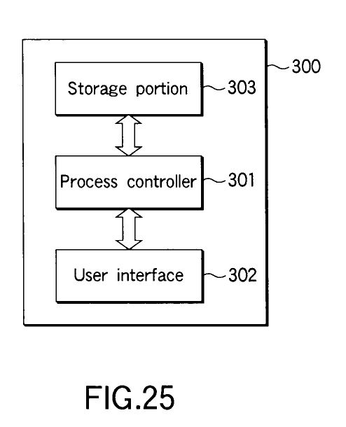

A temperature control mechanism 90 is disposed on the upper surface of the showerhead 40, and comprises a plurality of annular heaters 91 on the inner and outer sides, and a coolant passage 92 interposed between the heaters 91, for a coolant, such as cooling water, to flow therethrough. The detection signal of the thermo couple 10 is input into a process controller 301 of a control section 300 (see FIG. 25). Based on the detection signal, the process controller 301 outputs control signals into a heater power supply output unit 93 and a coolant source output unit 94 as feedback to the temperature control mechanism 90, thereby controlling the temperature of the showerhead 40.

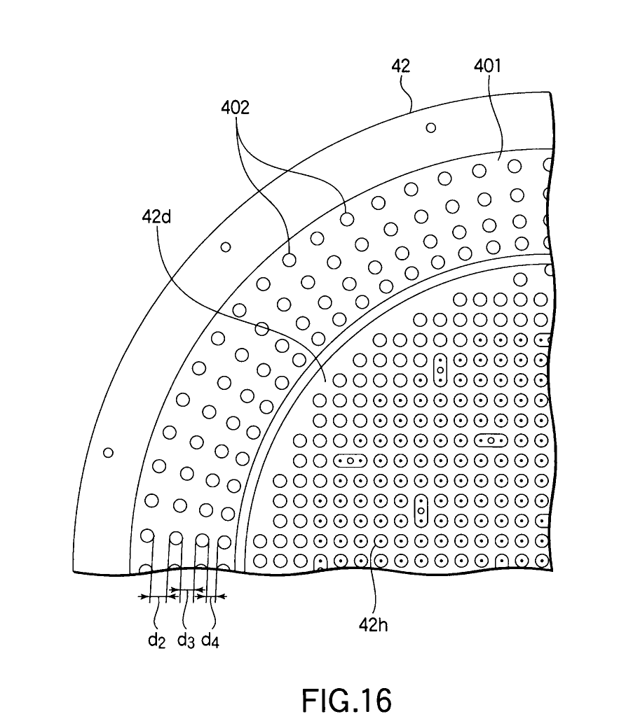

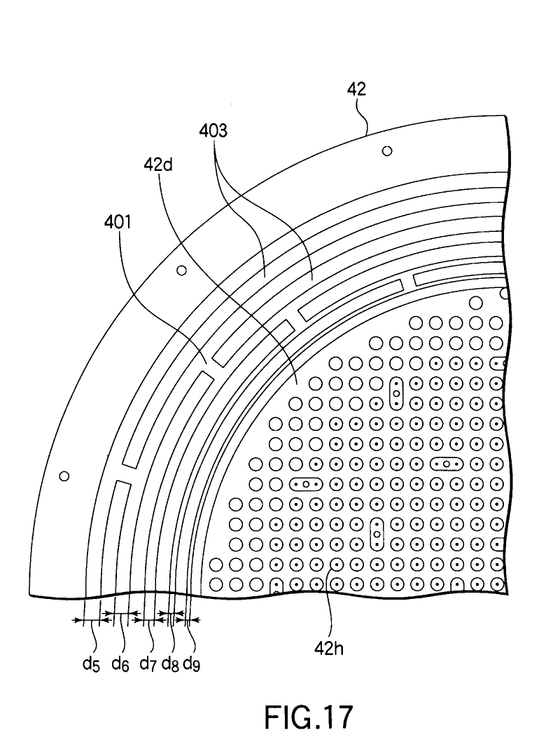

Each of FIGS. 16 and 17 is a view showing a gas diffusion plate 42 used for the showerhead 40 of a film forming apparatus according to an alternative embodiment. The apparatus according to each alternative embodiment has the same structure as the film forming apparatus shown in FIG. 1 except for the gas diffusion plate 42, and thus no explanation or illustration thereof will be given.

The gas diffusion plate 42 shown in FIG. 16 includes a recess 401 provided with a plurality of heat transfer columns 402 having a height to be in contact with a shower plate 43. The heat transfer columns 402 stand inside a temperature adjusting cell 400 and serve to promote heat conduction from the shower plate 43 to the gas diffusion plate 42. Where the heat transfer columns 402 are disposed, the volume of the heat-insulating space around the heat transfer columns 402 inside the temperature adjusting cell 400 is decreased. Accordingly, by use of the heat transfer columns 402, the heat-insulating property of the temperature adjusting cell 400 can be adjusted.

As shown in FIG. 16, the heat transfer columns 402 are formed of cylindrical columns, which are arrayed in a concentric pattern inside the recess 401. In this case, since the temperature of the showerhead 40 tends to decrease more at the peripheral portion, the number of heat transfer columns 402 is preferably set to be smaller, or the array intervals or cross sectional areas of the heat transfer columns 402 are preferably set to be smaller, toward the peripheral edge of the gas diffusion plate 42. As an example, in the case shown in FIG. 16, the array intervals of the heat transfer columns 402 are gradually increased toward the peripheral edge of the gas diffusion plate 42 (distances of d2>d3>d4). Consequently, the heat-insulating effect obtained by the internal space of the temperature adjusting cell 400 is adjusted in the radial direction to be larger at a position closer to the peripheral edge of the gas diffusion plate 42. By suitably setting the number, arrangement, and/or cross sectional areas of the heat transfer columns 402, the heat-insulating degree of the temperature adjusting cell 400 can be finely adjusted.

The shape of the heat transfer columns 402 is not limited to the cylindrical column shown in FIG. 16. For example, the shape may be a polygon, such as a triangle, rectangle, or octagon, as in the heat transfer columns 42e disposed inside the first gas diffusion area 42a. Further, the heat transfer columns 402 may be arrayed in a radial pattern in place of the concentric pattern, for example.

The gas diffusion plate 42 shown in FIG. 17 includes a recess 401 provided with a plurality of heat transfer walls 403 having a height to be in contact with a shower plate 43. The heat transfer walls 403 have an arched shape and are arrayed in a concentric pattern inside the recess 401. Also in this case, since the temperature of the showerhead 40 tends to decrease more at the peripheral portion, the distance between the heat transfer walls 403, the wall thickness (cross sectional area), or the number of heat transfer walls 403 arrayed in an annular direction is set to be smaller outward in the radial direction of the gas diffusion plate 42 (i.e., toward the peripheral edge of the gas diffusion plate 42). Consequently, the heat-insulating effect obtained by the internal space of the temperature adjusting cell 400 is adjusted to be larger at a position closer to the peripheral edge of the gas diffusion plate 42. As an example, in the case shown in FIG. 17, the array intervals of the heat transfer walls 403 are gradually increased toward the peripheral edge of the gas diffusion plate 42 (distances of d5>d6>d7>d8>d9). The heat transfer walls 403 may be arrayed in a radial pattern in place of the concentric pattern, for example.

The gas diffusion plate 42 shown in each of FIGS. 16 and 17 is usable as it is in the film forming apparatus shown in FIG. 1. Hence, no explanation or illustration will be given of the entire structure of a film forming apparatus provided with the gas diffusion plate 42 shown in either of FIGS. 16 and 17.

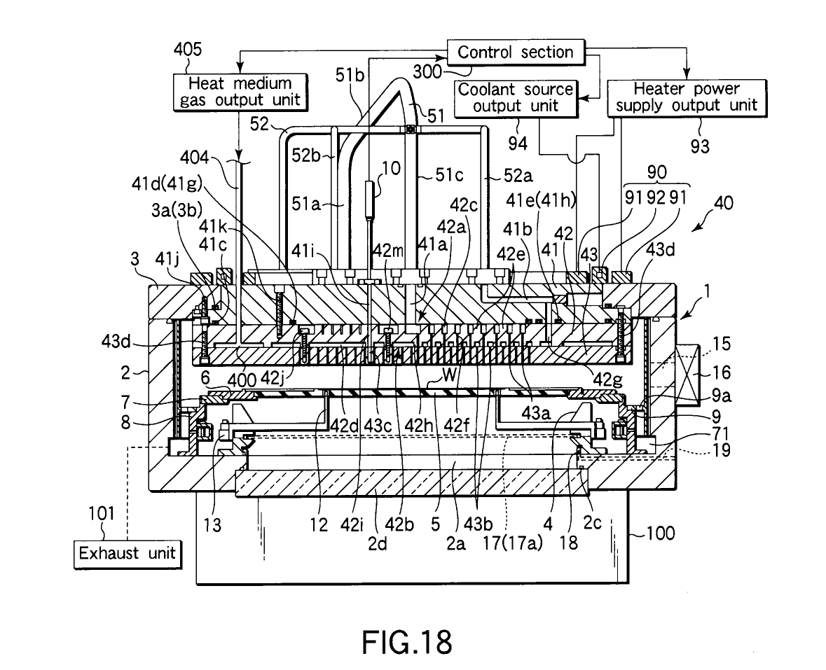

FIG. 18 is a view showing a film forming apparatus according to another alternative embodiment. This apparatus includes a temperature adjusting cell 400 defined by a recess 401 formed in a gas diffusion plate 42 and a shower plate 43. The temperature adjusting cell 400 is connected to a gas feed passage 404 for supplying a temperature adjusting medium, such as a heat medium gas, and a gas exhaust passage (not shown) for exhausting the heat medium gas. The gas feed passage 404 and gas exhaust passage are connected to a heat medium gas output unit 405. The heat medium gas output unit 405 includes a heating device and a pump (neither of them shown), so that the heat medium gas, such as an inactive gas, e.g., Ar or N₂, heated to a predetermined temperature is supplied through the gas feed passage 404 into the temperature adjusting cell 400 and then exhausted therefrom through the gas exhaust passage (not shown), in the form of circulation.

The heat medium gas is adjusted at a predetermined temperature and supplied into the temperature adjusting cell 400, so that the temperature decrease at the peripheral portion of the showerhead 40 is suppressed, and the temperature uniformity of the entire showerhead 40 is improved. As described above, according to this embodiment, since the heat medium gas adjusted at a predetermined temperature is supplied into the temperature adjusting cell 400, the temperature controllability of the showerhead 40 is further improved.

The apparatus shown in FIG. 18 has the same structure as the film forming apparatus shown in FIG. 1 except for the part described above. Hence, the same constituent elements are denoted by the same reference numerals, and their explanation will be omitted.

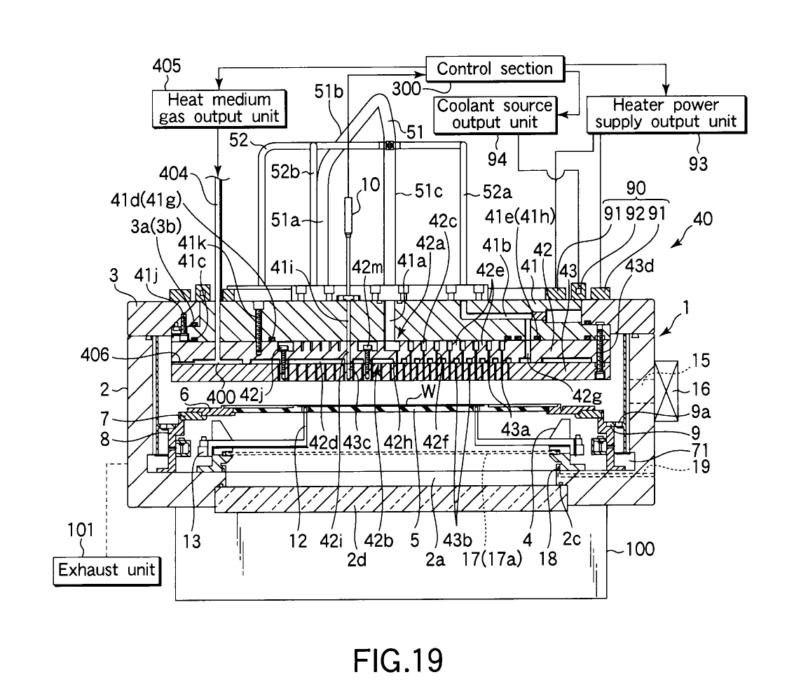

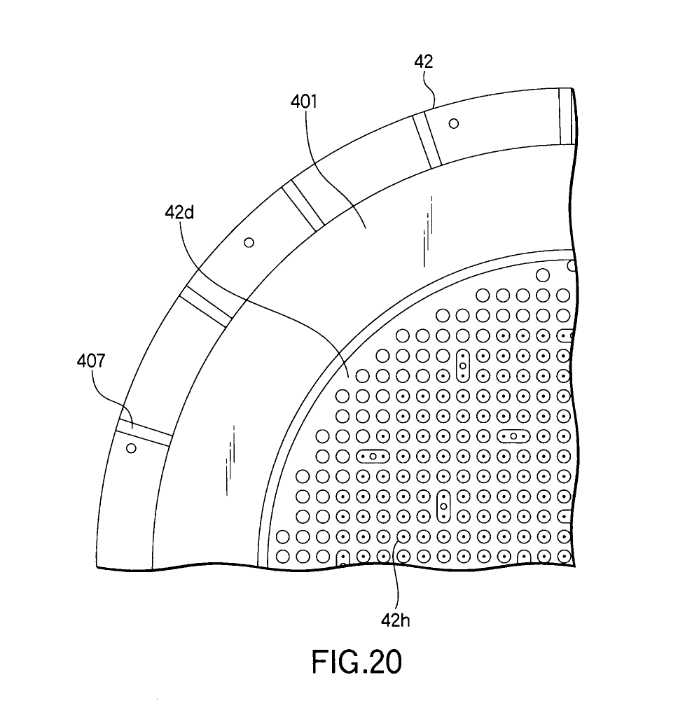

FIG. 19 is a view showing a modification of the embodiment shown in FIG. 18. In the embodiment shown in FIG. 18, the heat medium gas is circulated through the temperature adjusting cell 400 to control the temperature of the showerhead 40. In this respect, the embodiment shown in FIG. 19 includes a plurality of communication passages 406 that connect the temperature adjusting cell 400 to the space (process space) inside the process chamber 2. For example, as shown in FIG. 20, the lower surface of the gas diffusion plate 42 has thin grooves 407 formed therein in a radial pattern to extend outward from the recess 401. The thin grooves 407 defines the horizontally extending communication passages 406 between the gas diffusion plate 42 and shower plate 43 set in contact with each other.

According to this embodiment, the heat medium gas is supplied from the heat medium gas output unit 405 through the gas feed passage 404 into the temperature adjusting cell 400, and is discharged through the communication passages 406 into the process space. Consequently, the temperature of the showerhead 40 is controlled by the heat medium gas. The heat medium gas is kept supplied at a constant flow rate into the temperature adjusting cell 400, so that the process gas is not allowed to flow backward from the process space into the temperature adjusting cell 400.

According to this embodiment, the heat medium gas is supplied into the temperature adjusting cell 400, and is discharged through the communication passages 406 into the process space inside the process chamber 2. In this case, an operation for removing the heat medium gas is performed through the same exhaust route as that of the process gas. Since the operation for removing the heat medium gas does not have to be independently performed, the gas exhaust operations are advantageously unified by a simple exhaust route.

The apparatuses shown in FIGS. 18 and 19 have the same structure as the film forming apparatus shown in FIG. 1 except for the part described above. Hence, the same constituent elements are denoted by the same reference numerals, and their explanation will be omitted.

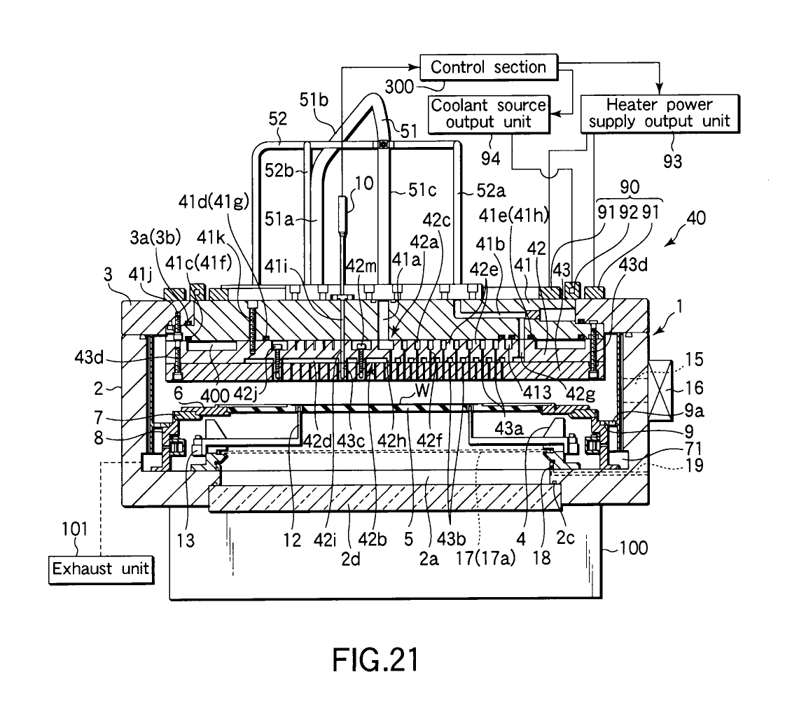

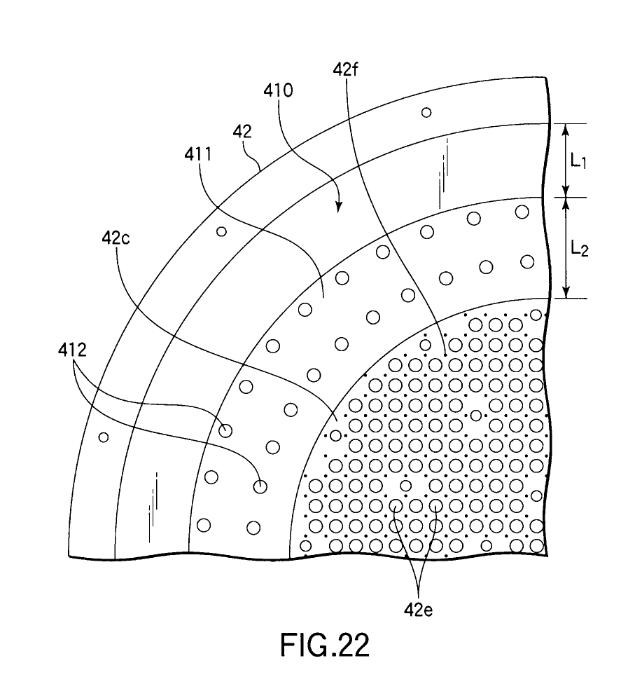

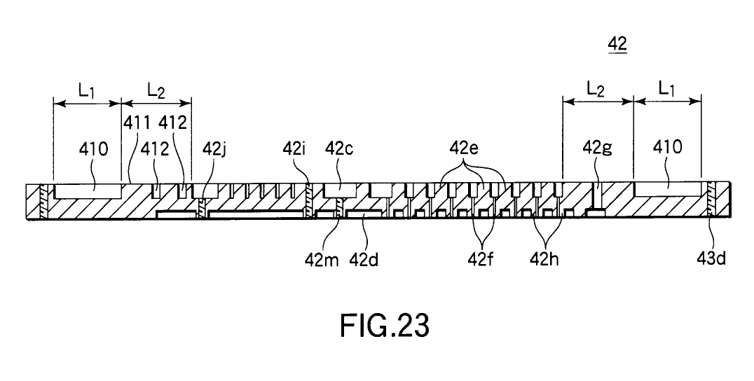

FIG. 21 is a view showing a film forming apparatus according to another alternative embodiment. FIG. 22 is a top plan view showing the upper surface of a gas diffusion plate 42, as a main portion thereof, used in this embodiment. FIG. 23 is a sectional view showing the gas diffusion plate 42. In the embodiments described above, the gas diffusion plate 42 includes the recess 401 on the lower surface to define the temperature adjusting cell 400 between the gas diffusion plate 42 and shower plate 43. In this respect, according to this embodiment, the gas diffusion plate 42 includes an annular groove recess 410 on the upper surface to define a temperature adjusting cell 400 between the gas diffusion plate 42 and shower base 41.

As shown in FIG. 22, on the upper surface of the gas diffusion plate 42, the annular recess 410 is separated from a recess (first gas diffusion space 42c) that defines a first gas diffusion area 42a, by a heat transfer portion 411 comprising an annular wall (protrusion). The heat transfer portion 411 promotes the heat transfer of the showerhead 40 upward through the shower base 41, so that the temperature of the showerhead 40 at the area (intermediate area) between the central portion and peripheral portion is prevented from excessively increasing.

For example, the heat transfer portion 411 has a plurality of holes 412 formed therein, so that the holes 412 respectively form small heat-insulating cells 413 between the gas diffusion plate 42 and shower base 41 laminated each other. Accordingly, by suitably setting the number, size (surface area), and/or arrangement of the holes 412, the heat transfer amount from the heat transfer portion 411 to the shower base 41 can be adjusted. In this embodiment, the holes 412 are arrayed at predetermined intervals in two annular rows, for example. The holes 412 can be arrayed in any pattern, such as a concentric or staggered pattern, as long as the heat transfer amount through the heat transfer portion 411 is adjusted. Each of the holes 412 may have another plan view shape, such as a rectangle triangle, or ellipse. In place of the holes 412, a groove may be formed in the heat transfer portion 411.

As described above, the temperature adjusting cell 400 is defined by the recess 410, and a plurality of heat-insulating cells 413 is defined by the holes 412 formed in the heat transfer portion 411, between the gas diffusion plate 42 and shower base 41 laminated each other. By setting the conditions of the cell 400 and cells 413 as well as the heat transfer portion 411, the temperature of the showerhead 40 can be finely controlled. Specifically, due to the heat-insulating effect obtained by the internal space of the temperature adjusting cell 400, the temperature of the showerhead 40 is prevented from being far lower at the peripheral portion than at the central portion. Further, the temperature at the area (intermediate area) between the peripheral portion and central portion can be adjusted by the heat transfer portion 411 and heat-insulating cells 413, so that the temperature of the intermediate area is prevented from excessively increasing. As shown in FIGS. 22 and 23, in this embodiment, the ratio between the width L1 of the recess 410 and the width L2 of the heat transfer portion 411 is set to be essentially 1:1, so that the temperature of the showerhead 40 becomes uniform over the central portion, peripheral portion, and intermediate area therebetween. The ratio (L1:L2) between the width L1 of the recess 410 and the width L2 of the heat transfer portion 411 can be arbitrarily set, but the ratio is preferably set to, e.g., 3:1 to 1:1 to uniformize the temperature of the showerhead 40.

The apparatus shown in FIGS. 21 to 23 has the same structure as the film forming apparatus shown in FIG. 1 except for the part described above. Hence, the same constituent elements are denoted by the same reference numerals, and their explanation will be omitted.

It should be noted that, also in this embodiment, the recess 410 may be provided with heat transfer columns or heat transfer wall having a height to be in contact with the shower base 41, as in the embodiments described above (see FIGS. 16 and 17).

The temperature adjusting cell 400 defined by the recess 410 and shower base 41 may be provided with a structure for supplying a heat medium gas therein (see FIG. 18). In this case, a plurality of thin grooves may be formed from the recess 410 to the peripheral edge of the gas diffusion plate 42 for the temperature adjusting cell 400 to communicate with the process space (see FIGS. 19 and 20).

Next, an explanation will be given of a gas supply source section 60 for supplying various gases through the showerhead 40 into the process chamber 2, with reference to FIG. 24.

The gas supply source section 60 includes a vaporizer 60h for generating a source gas, and a raw material tank 60a, a raw material tank 60b, a raw material tank 60c, and a solvent tank 60d for supplying liquid raw materials (organic metal compounds) and so forth into the vaporizer 60h. Where a PZT thin film is formed, for example, liquid raw materials adjusted at a predetermined temperature are used along with an organic solvent, such that the raw material tank 60a stores Pb(thd)₂, the raw material tank 60b stores Zr(dmhd)₄, and the raw material tank 60c stores Ti(OiPr)₂(thd)₂. Another example of the raw materials is a combination of Pb(thd)₂, Zr(OiPr)₂(thd)₂, and Ti(OiPr)₂(thd)₂.

The solvent tank 60d stores CH₃COO(CH₂)₃CH₃ (butyl acetate), for example. Another example of the solvent is CH₃(CH₂)₆CH₃ (n-octane).

Each of the raw material tanks 60a to 60c is connected to the vaporizer 60h through a flow meter 60f and a raw material supply control valve 60g. The vaporizer 60h is connected to a carrier (purge) gas source 60i through a purge gas supply control valve 60j, a flow rate control section 60n, and a mixing control valve 60p, so that each of the liquid source gas is supplied into the vaporizer 60h.

The solvent tank 60d is connected to a vaporizer 60h through a fluid flow meter 60f and a raw material supply control valve 60g. He gas is supplied from a pressurized gas source into the raw material tanks 60a to 60c and solvent tank 60d, so that the liquid raw materials and solvent are supplied from the tanks by the pressure of He gas. They are supplied into the vaporizer 60h at a predetermined mixture ratio, and are vaporized to generate a source gas, which is then sent to the source gas line 51 and supplied through a valve 62a disposed in a valve block 61 into the showerhead 40.

The gas supply source section 60 includes a carrier (purge) gas source 60i for supplying an inactive gas, such as Ar, He, or N₂, to the purge gas passages 53 and 19 through a purge gas supply control valve 60j, valves 60s and 60x, flow rate control sections 60k and 60y, and valves 60t and 60z. The gas supply source section 60 further includes an oxidizing agent gas source 60q for supplying an oxidizing agent (gas), such as NO₂, N₂O, O₂, O₃, or NO, to the oxidizing agent gas line 52 through an oxidizing agent gas supply control valve 60r, a valve 60v, a flow rate control section 60u, and a valve 62b disposed in the valve block 61.

When the raw material supply control valve 60g are set closed, a carrier gas can be supplied from the carrier (purge) gas source 60i through the valve 60w, flow rate control section 60n, and mixing control valve 60p into the vaporizer 60h, so that the vaporizer 60h and source gas line 51 are purged by a carrier gas, such as Ar, to remove the unnecessary source gas therefrom, as needed. Similarly, the carrier (purge) gas source 60i is connected to the oxidizing agent gas line 52 through a mixing control valve 60m, so that the associated piping lines can be purged by a carrier gas, such as Ar, to remove the oxidizing agent gas therefrom, as needed. Further, the carrier (purge) gas source 60i is connected to a portion of the source gas line 51 downstream from the valve 62a through the valve 60s, flow rate control section 60k, valve 60t, and a valve 62c disposed in the valve block 61, so that the downstream side of the source gas line 51 can be purged by a carrier gas, such as Ar, when the valve 62a is set closed.

Respective components of the film forming apparatus shown in each of FIGS. 1, 18, 19, and 21 are connected to and controlled by a control section 300. FIGS. 1 and 21 only show as representatives the connections of the control section 300 to the thermo couple 10, heater power supply output unit 93, and coolant source output unit 94. Similarly, FIGS. 18 and 19 only show as representatives the connections of the control section 300 to the thermo couple 10, heater power supply output unit 93, coolant source output unit 94, and heat medium gas output unit 405.

For example, as shown in FIG. 25, the control section 300 includes a process controller 301 comprising a CPU. The process controller 301 is connected to a user interface 302, which includes, e.g., a keyboard and a display, wherein the keyboard is used for a process operator to input commands for operating the film forming apparatus, and the display is used for showing visualized images of the operational status of the film forming apparatus.

The process controller 301 is further connected to a storage portion 303, which stores recipes with control programs (software) and process condition data recorded therein for realizing various processes performed in the film forming apparatus under the control of the process controller 301.

A required recipe is retrieved from the storage portion 303 and executed by the process controller 301 in accordance with an instruction or the like input through the user interface 302. Consequently, a predetermined process is performed in the film forming apparatus under the control of the process controller 301. Recipes with control programs and process condition data recorded therein may be stored in a computer readable storage medium, such as a CD-ROM, hard disk, flexible disk, or flash memory. Further, recipes may be utilized on-line, while it is transmitted from another apparatus through, e.g., a dedicated line, as needed.

Next, an explanation will be given of an operation of the film forming apparatus having the structure described above.

At first, the interior of the process chamber 2 is exhausted by a vacuum pump (not shown) through an exhaust route comprising the bottom exhaust passage 71, exhaust confluence portions 72, upward exhaust passages 73, horizontal exhaust pipe 74, and downward exhaust passage 75, so that it is set at a vacuum level of, e.g., about 100 to 550 Pa.

At this time, a purge gas, such as Ar, is supplied from the carrier (purge) gas source 60i through the purge gas passage 19 and a plurality of gas spouting holes 18 to the backside (lower surface) of the gas shield 17. The purge gas flows through the holes 17a of the gas shield 17 to the backside of the worktable 5, and then flows through a clearance of the shield base 8 into the bottom exhaust passage 71. Consequently, a steady purge gas flow is formed to prevent damage, such as thin film deposition and/or etching, from being caused on the transmission window 2d located below the gas shield 17.

While the process chamber 2 is set in this state, the lifter pins 12 are moved up to project upward from the worktable 5, and a wafer W is loaded by, e.g., a robot hand mechanism (not shown) through the gate valve 16 and wafer transfer port 15 onto the lifter pins 12. Thereafter, the gate valve 16 is closed.

Then, the lifter pins 12 are moved down to place the wafer W onto the worktable 5. Further, the lamp unit (not shown) is turned on to radiate heat rays through the transmission window 2d onto the lower surface (backside) of the worktable 5. Consequently, the wafer W placed on the worktable 5 is heated to a temperature of, e.g., 400° C. to 700° C., such as 600 to 650° C.

Further, the pressure inside the process chamber 2 is adjusted at a pressure of 133.3 to 666 Pa (1 to 5 Torr).

After the wafer W is set at the heating temperature, a source gas and an oxidizing agent (gas), such as O₂, are supplied from the gas supply source section 60 and are delivered through first gas delivery holes 43a and second gas delivery holes 43b of the shower plate 43 on the bottom of the showerhead 40. At this time, for example, the source gas is prepared by mixing Pb(thd)₂, Zr(dmhd)₄, and Ti(OiPr)₂(thd)₂ at a predetermined ratio (for example, a stoichiometric ratio determined by the elements of PZT, such as Pb, Zr, Ti, and O. The source gas and oxidizing agent gas cause thermal decomposition reactions and mutual chemical reactions, thereby forming a PZT thin film on the surface of the wafer W.

Specifically, the vaporized source gas from the vaporizer 60h of the gas supply source section 60 flows along with a carrier gas, through the source gas line 51, and the first gas diffusion space 42c and first gas passages 42f of the gas diffusion plate 42, and is then delivered from the first gas delivery holes 43a of the shower plate 43, into the space above the wafer W. Similarly, the oxidizing agent gas from the oxidizing agent gas source 60q flows through the oxidizing agent gas line 52, the oxidizing agent gas branch line 52a, the second gas feed passages 41b of the shower base 41, and the second gas passages 42g of the gas diffusion plate 42 to the second gas diffusion space 42d, and is then delivered from the second gas delivery holes 43b of the shower plate 43, into the space above the wafer W. The source gas and oxidizing agent gas are not mixed in the showerhead 40 before they are supplied into the process chamber 2. The supply time of the source gas and oxidizing agent gas is adjusted to control the thickness of a thin film to be formed on the wafer W. At this time, the temperature adjusting cell 400 formed in the showerhead 40 is used to control the temperature of the peripheral portion of the showerhead 40, so that the temperature of showerhead 40 becomes uniform to form a film with a uniform film composition.

As described above, the film forming apparatus according to an embodiment of the present invention includes the temperature adjusting cell 400 in the showerhead 40. Consequently, the peripheral portion of the showerhead 40 can be effectively prevented from decreasing its temperature.

Further, at the central portion of the showerhead 40, the first gas diffusion area 42a is provided with the heat transfer columns 42e, and the second gas diffusion area 42b is provided with the cylindrical column projections 42h. Consequently, the heat-insulating effect of the gas diffusion space is decreased to prevent the central portion of the showerhead 40 from being overheated.

It follows that the temperature of the showerhead 40 becomes uniform to improve film formation characteristics.

The present invention is not limited to the embodiments described above, and it may be modified in various manners within the spirit or scope of the present invention. For example, the embodiments described above are exemplified by a process for forming a PZT thin film. Alternatively, the present invention may be applied to a process for forming another film of, e.g., BST, STO, PZTN, PLZT, SBT, Ru, RuO₂, or BTO. Further, the present invention may be applied to a process for forming another film of, e.g., W or Ti.

As a gas processing apparatus other than the film forming apparatus, the present invention may be applied to, e.g., a heat processing apparatus or plasma processing apparatus.

The target substrate is not limited to a semiconductor wafer, and it may be another substrate, such as that of a flat panel display (FPD), a representative of which is a glass substrate of a liquid crystal display device (LCD). Further, the present invention may be applied to a case where the target object is a compound semiconductor substrate.

### INDUSTRIAL APPLICABILITY

The present invention is widely usable for substrate processing apparatuses in which a predetermined process is performed while a source gas is supplied onto a substrate placed and heated on a worktable, from a showerhead disposed opposite thereto inside a process chamber.

1. A substrate processing apparatus comprising:
a process chamber configured to accommodate a target substrate;
a worktable disposed inside the process chamber and configured to place the target substrate thereon;
a process gas delivery mechanism disposed to face the target substrate on the worktable and configured to delivery a process gas into the process chamber; and
an exhaust mechanism configured to exhaust gas from inside the process chamber,
wherein the process gas delivery mechanism has a multi-layered structure comprising a plurality of plates having a gas passage formed therein for supplying the process gas, and
the multi-layered structure includes an annular temperature adjusting cell formed therein around the gas passage.

2. The substrate processing apparatus according to claim 1, wherein the multi-layered structure comprises
a first plate from which the process gas is introduced,
a second plate set in contact with a main surface of the first plate, and
a third plate set in contact with the second plate and having a plurality of gas delivery holes formed therein according to the target substrate placed on the worktable.

3. The substrate processing apparatus according to claim 2, wherein the temperature adjusting cell is defined by a recess formed in any one of the first plate, the second plate, or the third plate and a plate surface adjacent thereto.

4. The substrate processing apparatus according to claim 3, wherein the temperature adjusting cell is defined by an annular recess formed on the lower surface of the second plate and an upper surface of the third plate.

5. The substrate processing apparatus according to claim 4, wherein the recess is provided with a plurality of heat transfer columns formed therein and set in contact with an adjacent plate.

6. The substrate processing apparatus according to claim 5, wherein the heat transfer columns are arrayed in a concentric pattern with array intervals set to be larger toward an outer perimeter of the plates.

7. The substrate processing apparatus according to claim 5, wherein the heat transfer columns are arrayed in a concentric pattern with cross sectional areas set to be smaller toward an outer perimeter of the plates.

8. The substrate processing apparatus according to claim 4, wherein the recess is provided with a plurality of heat transfer walls formed therein and set in contact with an adjacent plate.

9. The substrate processing apparatus according to claim 8, wherein the heat transfer walls are arrayed in a concentric pattern with array intervals set to be larger toward an outer perimeter of the plates.

10. The substrate processing apparatus according to claim 8, wherein the heat transfer walls are arrayed in a concentric pattern with cross sectional areas set to be smaller toward an outer perimeter of the plates.

11. The substrate processing apparatus according to claim 3, wherein the temperature adjusting cell is defined by a lower surface of the second plate and an annular recess formed on the upper surface of the third plate.

12. The substrate processing apparatus according to claim 11, wherein the recess is provided with a plurality of heat transfer columns formed therein and set in contact with an adjacent plate.

13. The substrate processing apparatus according to claim 12, wherein the heat transfer columns are arrayed in a concentric pattern with array intervals set to be larger toward an outer perimeter of the plates.

14. The substrate processing apparatus according to claim 12, wherein the heat transfer columns are arrayed in a concentric pattern with cross sectional areas set to be smaller toward an outer perimeter of the plates.

15. The substrate processing apparatus according to claim 11, wherein the recess is provided with a plurality of heat transfer walls formed therein and set in contact with an adjacent plate.

16. The substrate processing apparatus according to claim 15, wherein the heat transfer walls are arrayed in a concentric pattern with array intervals set to be larger toward an outer perimeter of the plates.

17. The substrate processing apparatus according to claim 15, wherein the heat transfer walls are arrayed in a concentric pattern with cross sectional areas set to be smaller toward an outer perimeter of the plates.

18. The substrate processing apparatus according to claim 1, wherein the process gas delivery mechanism further includes a feed passage for supplying a temperature adjusting medium into the temperature adjusting cell and an exhaust passage for exhausting the temperature adjusting medium.

19. The substrate processing apparatus according to claim 1, wherein the process gas delivery mechanism further includes a feed passage for supplying a temperature adjusting medium into the temperature adjusting cell, and the temperature adjusting cell is set to communicate with a process space inside the process chamber.

20. The substrate processing apparatus according to claim 2, wherein the third plate has a plurality of first delivery holes for delivering a first process gas and a plurality of second delivery holes for delivering a second process gas.

21. The substrate processing apparatus according to claim 20, wherein the gas passage is provided with a first gas diffusion area disposed between the first plate and the second plate, and a second gas diffusion area disposed between the second plate and the third plate,
wherein the first gas diffusion area includes a plurality of first columns connected to the first plate and the second plate, and a first gas diffusion space forming a portion other than the plurality of first columns and communicating the first gas delivery holes,
wherein the second gas diffusion area includes a plurality of second columns connected to the second plate and the third plate, and a second gas diffusion space forming a portion other than the plurality of second columns and communicating the second gas delivery holes, and
wherein the first process gas is supplied through the first gas diffusion space and delivered from the first gas delivery holes, and the second process gas is supplied through the second gas diffusion space and delivered from the second gas delivery holes.

22. The substrate processing apparatus according to claim 21, wherein the plurality of second columns respectively have gas passages formed therein in an axial direction for the first gas diffusion space to communicate with the first gas delivery holes.

23. A process gas delivery mechanism for delivering a process gas into a process chamber in which a gas process is performed on a target substrate by use of the process gas thus supplied, the process gas delivery mechanism comprising:
a multi-layered structure comprising a plurality of plates having a gas passage formed therein for supplying the process gas,
wherein the multi-layered structure includes an annular temperature adjusting cell formed therein around the gas passage.

24. The process gas delivery mechanism according to claim 23, wherein the multi-layered structure comprises
a first plate from which the process gas is introduced,
a second plate set in contact with a main surface of the first plate, and
a third plate set in contact with the second plate and having a plurality of gas delivery holes formed therein according to the target substrate placed on the worktable.

25. The process gas delivery mechanism according to claim 24, wherein the temperature adjusting cell is defined by a recess formed in any one of the first plate, the second plate, or the third plate and a plate surface adjacent thereto.

26. The process gas delivery mechanism according to claim 25, wherein the temperature adjusting cell is defined by an annular recess formed on the lower surface of the second plate and an upper surface of the third plate.

27. The process gas delivery mechanism according to claim 26, wherein the recess is provided with a plurality of heat transfer columns formed therein and set in contact with an adjacent plate.

28. The process gas delivery mechanism according to claim 27, wherein the heat transfer columns are arrayed in a concentric pattern with array intervals set to be larger toward an outer perimeter of the plates.

29. The process gas delivery mechanism according to claim 27, wherein the heat transfer columns are arrayed in a concentric pattern with cross sectional areas set to be smaller toward an outer perimeter of the plates.

30. The process gas delivery mechanism according to claim 25, wherein the recess is provided with a plurality of heat transfer walls formed therein and set in contact with an adjacent plate.

31. The process gas delivery mechanism according to claim 30, wherein the heat transfer walls are arrayed in a concentric pattern with array intervals set to be larger toward an outer perimeter of the plates.

32. The process gas delivery mechanism according to claim 30, wherein the heat transfer walls are arrayed in a concentric pattern with cross sectional areas set to be smaller toward an outer perimeter of the plates.

33. The process gas delivery mechanism according to claim 25, wherein the temperature adjusting cell is defined by a lower surface of the second plate and an annular recess formed on the upper surface of the third plate.

34. The process gas delivery mechanism according to claim 33, wherein the recess is provided with a plurality of heat transfer columns formed therein and set in contact with an adjacent plate.

35. The process gas delivery mechanism according to claim 34, wherein the heat transfer columns are arrayed in a concentric pattern with array intervals set to be larger toward an outer perimeter of the plates.

36. The process gas delivery mechanism according to claim 34, wherein the heat transfer columns are arrayed in a concentric pattern with cross sectional areas set to be smaller toward an outer perimeter of the plates.

37. The process gas delivery mechanism according to claim 33, wherein the recess is provided with a plurality of heat transfer walls formed therein and set in contact with an adjacent plate.

38. The process gas delivery mechanism according to claim 37, wherein the heat transfer walls are arrayed in a concentric pattern with array intervals set to be larger toward an outer perimeter of the plates.

39. The process gas delivery mechanism according to claim 37, wherein the heat transfer walls are arrayed in a concentric pattern with cross sectional areas set to be smaller toward an outer perimeter of the plates.

40. The process gas delivery mechanism according to claim 23, wherein the mechanism further comprises a feed passage for supplying a temperature adjusting medium into the temperature adjusting cell and an exhaust passage for exhausting the temperature adjusting medium.

41. The process gas delivery mechanism according to claim 23, wherein the mechanism further comprises a feed passage for supplying a temperature adjusting medium into the temperature adjusting cell, and the temperature adjusting cell is set to communicate with a process space inside the process chamber.

42. The process gas delivery mechanism according to claim 24, wherein the third plate has a plurality of first delivery holes for delivering a first process gas and a plurality of second delivery holes for delivering a second process gas.

43. The process gas delivery mechanism according to claim 42, wherein the gas passage is provided with a first gas diffusion area disposed between the first plate and the second plate, and a second gas diffusion area disposed between the second plate and the third plate,
wherein the first gas diffusion area includes a plurality of first columns connected to the first plate and the second plate, and a first gas diffusion space forming a portion other than the plurality of first columns and communicating the first gas delivery holes,
wherein the second gas diffusion area includes a plurality of second columns connected to the second plate and the third plate, and a second gas diffusion space forming a portion other than the plurality of second columns and communicating the second gas delivery holes, and
wherein the first process gas is supplied through the first gas diffusion space and delivered from the first gas delivery holes, and the second process gas is supplied through the second gas diffusion space and delivered from the second gas delivery holes.

44. The process gas delivery mechanism according to claim 43, wherein the plurality of second columns respectively have gas passages formed therein in an axial direction for the first gas diffusion space to communicate with the first gas delivery holes.
